(19) United States
(12) Patent Application Publication
(10) Pub. No.: US 2004/0224237 A1
(43) Pub. Date: Nov. 11, 2004

(54) Whole new mask repair method

(75) Inventors: Tzy-Ying Lin, Hsin-Chu (TW); Chue-San Yoo, Hsin-chu (TW); Chin-Wang Hu, Jubei City (TW); Ming-Chih Hsieh, Hsin-chu (TW); Ming-Feng Ho, Hsinchu (TW); Cheng-Hung Kung, Hsin Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/431,858

(22) Filed: May 8, 2003

(51) Int. Cl. G01B 7/00; G03F 9/00; G21K 5/10; G06F 15/00; G01B 15/00; H01J 37/08

(52) U.S. Cl. 430/5; 250/492.21; 702/155; 250/492.2

(57) ABSTRACT

A method for repairing a defective photomask having contained therein a minimum of one defect first provides forming a masking layer upon the defective photomask such as to leave exposed the minimum of one defect. Within the invention the minimum of one defect within the defective photomask may be repaired while employing the masking layer as a defect repair masking layer, to thus form a repaired photomask from the defective photomask. The method provides for efficient repairing of the defective photomask, absent transparent substrate damage.

### BACKGROUND OF THE INVENTION

1. Field of the Invention

The present invention relates generally to methods for repairing photomasks employed for fabricating microelectronic products. More particularly, the present invention relates to methods for efficiently repairing photomasks employed for fabricating microelectronic products.

2. Description of the Related Art

Common in the microelectronic product fabrication art is the use of photomasks for purposes of defining patterned photoresist layers which in turn are employed for defining patterned microelectronic layers and patterned microelectronic structures when fabricating microelectronic products.

While photomasks are clearly desirable and often essential in the microelectronic product fabrication art, photomasks are nonetheless not entirely without problems in the microelectronic product fabrication art. In that regard, photomasks often suffer from defects which are difficult to efficiently repair since photomask repair methods often employ focused ion beam or laser beam methods and apparatus which often provide for a lengthy cycle time for photomask repair.

It is thus desirable to provide methods for efficiently repairing photomasks employed for fabricating microelectronic products. It is towards the foregoing object that the present invention is directed.

Various methods for repairing photomasks have been disclosed in the microelectronic product fabrication art.

Included but not limiting among the methods are methods disclosed within: (1) Yedur et al., in U.S. Pat. No. 6,197,455 (a scanning tunneling microscopy method for repairing a photomask); and (2) Harricott et al., in U.S. Pat. No. 6,368,753 (a gallium ion beam method for repairing a photomask).

Desirable are additional methods for efficiently repairing photomasks employed for fabricating microelectronic products.

It is towards the foregoing object that the present invention is directed.

### SUMMARY OF THE INVENTION

A first object of the invention is to provide a method for repairing a photomask.

A second object of the invention is to provide a method in accord with the first object of the invention, wherein the photomask is efficiently repaired.

In accord with the objects of the invention, the invention provides a method for repairing a photomask.

To practice the method of the present invention, there is provided a defective photomask having contained therein a minimum of one defect. There is then formed upon the defective photomask a masking layer which leaves exposed the minimum of one defect. Finally, there is then repaired within the defective photomask the minimum of one defect while employing the masking layer as a defect repair masking layer, to thus form from the defective photomask a repaired photomask. Thus, the invention may be employed for repairing a photomask having formed therein a single defect or greater than the single defect.

The present invention provides a method for repairing a photomask, wherein the photomask is efficiently repaired.

The present invention realizes the foregoing object by masking areas of a photomask other than those having contained therein a minimum of one defect such that the minimum of one defect may be repaired while employing the masking layer as a defect repair masking layer.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1, FIG. 2, FIG. 3, FIG. 4 and FIG. 5 show a series of schematic cross-sectional and plan-view diagrams illustrating the results of progressive stages of repairing a defective photomask in accord with a first preferred embodiment of the invention.

FIG. 6 and FIG. 7 show a pair of schematic cross-sectional diagrams illustrating the results of progressive stages of repairing a defective photomask in accord with a second preferred embodiment of the invention.

### DESCRIPTION OF THE PREFERRED EMBODIMENT

The present invention provides a method for repairing a photomask, wherein the photomask is efficiently repaired.

The present invention realizes the foregoing object by masking areas of a photomask other than those having contained therein a minimum of one defect such that the minimum of one defect may be repaired while employing the masking layer as a defect repair masking layer.

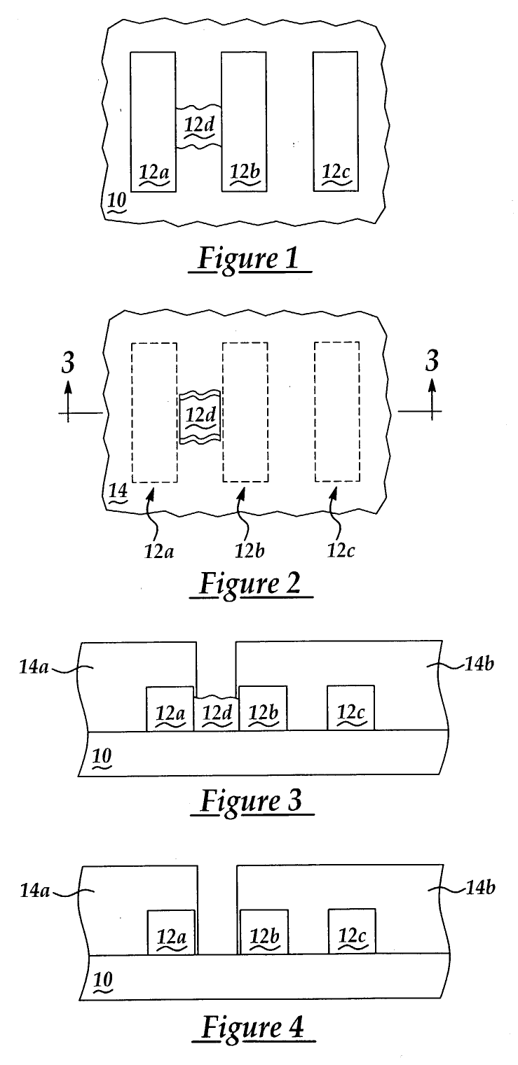

FIG. 1 to FIG. 5 show a series of schematic cross-sectional and plan-view diagrams illustrating the results of progressive stages of repairing a defective photomask in accord with a first preferred embodiment of the invention.

FIG. 1 shows a schematic plan-view diagram of the defective photomask at an early stage in its repair in accord with the first preferred embodiment of the invention.

FIG. 1 shows a transparent substrate 10 having formed thereupon a series of opaque mask pattern layers 12a, 12b and 12c, as well as an opaque mask pattern layer defect 12d.

Within the invention, the transparent substrate 10 is typically a transparent quartz substrate, although transparent substrates formed of other transparent materials which are transparent to particular wavelengths of photoexposure light may also be employed. Typically, the transparent substrate 10 is formed to a thickness of from about 2 to about 6 millimeters.

Within the invention, the series of opaque mask pattern layers 12a, 12b and 12c is typically formed of an opaque metal material, such as but not limited to an opaque aluminum metal material or an opaque chromium metal material, formed to a thickness of from about 500 to about 1000 angstroms upon the transparent substrate 10. Typically, the series of opaque mask pattern layers 12a, 12b and 12c is each formed of a linewidth from about 0.065 to about 2.0 μm, with a similar separation distance.

Within the invention, the opaque mask pattern layer defect 12d is typically formed of an opaque metal material identical to the opaque metal material which is employed for forming the series of opaque mask pattern layers 12a, 12b and 12c. Typically, the opaque mask pattern layer defect 12d is formed unintentionally incident to a blanket opaque mask material layer patterning error when forming the series of opaque mask pattern layers 12a, 12b and 12c from the blanket opaque mask material layer. Typically, the opaque mask pattern layer defect 12d covers an area of from about 0.1 to about 100 μm interposed between the pair of opaque mask pattern layers 12a and 12b.

FIG. 2 shows a schematic plan-view diagram illustrating the results of further processing of the defective photomask whose schematic plan-view diagram is illustrated in FIG. 1.

FIG. 2 shows a patterned masking layer 14 which is formed upon and covering exposed portions of the transparent substrate 10 and the series of opaque mask pattern layers 12a, 12b and 12c, but neither upon nor covering the exposed portions of the opaque mask pattern layer defect 12d.

Within the invention, the patterned masking layer 14 may be formed of masking materials including but not limited to photoresist masking materials and hard masking materials. More typically, the patterned masking layer 14 is formed of a photoresist masking material formed to a thickness of from about 1000 to about 5000 angstroms.

As is understood by a person skilled in the art, the patterned masking layer 14 when formed of a photoresist masking material is preferably formed of a positive photoresist masking material. A blanket layer of the positive photoresist masking material is selectively photoexposed only in the region of the opaque mask pattern layer defect 12d (and any other opaque mask pattern layer defects which may also be present within the defective photomask as illustrated in FIG. 1 (i.e., the present invention is applicable to repairing photomasks having formed therein a minimum of one defect) but otherwise completely covers remaining exposed portions of the transparent substrate 10 and the series of opaque mask pattern layers 12a, 12b and 12c. The blanket layer of the selectively photoexposed positive photoresist material may then be developed to form the patterned masking layer 14. Within the invention, it is intended that the blanket layer of positive photoresist material may be photoexposed in the process of forming the patterned masking layer 14 with considerably enhanced efficiency in comparison with an amount of processing time which might be consumed for directly ablating the opaque mask pattern layer defect 12d while employing a focused ion beam etching or laser beam etching method. The blanket layer of positive photoresist material may be photoexposed employing methods including but not limited to scanning electron microscopy methods, electron beam methods, ion beam methods or any other fine linewidth radiation source methods of appropriate radiation density and intensity, in addition to optical irradiation methods.

FIG. 3 shows a schematic cross-sectional diagram of a defective photomask corresponding with the schematic plan-view diagram of FIG. 2.

FIG. 3 illustrates the transparent substrate 10 having formed thereupon the series of opaque mask pattern layers 12a, 12b and 12c as well as the opaque mask pattern layer defect 12d. FIG. 3 also illustrates a pair of patterned masking layers 14a and 14b which are representative of, and derived from, the patterned masking layer 14 as illustrated in FIG. 2.

FIG. 4 illustrates the results of further processing of the defective photomask of FIG. 3.

FIG. 4 shows the defective photomask of FIG. 3 from which has been etched the opaque mask pattern layer defect 12d while simultaneously leaving unetched the pair of opaque mask pattern layers 12a and 12b. As is illustrated in FIG. 4, the opaque mask pattern layer defect 12d is etched and removed while employing the pair of patterned masking layers 14a and 14b as a mask defect repair mask. Within the invention, the opaque mask pattern layer defect 12d may be etched and removed from the defective photomask as illustrated in FIG. 3 to provide a repaired photomask as illustrated in FIG. 4 while employing etch methods as are conventional or unconventional in the mask fabrication art. Such etch methods may include, but are not limited to wet chemical etch methods and dry plasma etch methods. Under circumstances where the opaque mask pattern layer defect 12d is formed of a chromium material, such wet chemical etch methods typically employ HcL₀₄ wet chemical etchants and such dry plasma etch methods typically employ chlorine base etching gas. Within the invention, it is intended that the wet chemical etch methods and dry plasma etch methods may be more chemically selective for etching a metal mask material from which is formed the opaque mask pattern layer defect 12d in comparison with a transparent material from which is formed the transparent substrate 10. Thus, it is also intended that in addition to a more rapid removal of the opaque mask pattern layer defect 12d in comparison with a focused ion beam etching, the invention also provides attenuated transparent substrate 10 damage.

FIG. 5 shows a schematic plan-view diagram illustrating the results of further processing of the repaired photomask whose schematic cross-sectional diagram is illustrated in FIG. 4.

FIG. 5 illustrates a schematic plan-view diagram corresponding with the schematic cross-sectional diagram of FIG. 4, but wherein the pair of patterned masking layers 14a and 14b has been stripped from portions of the transparent substrate 10 and the series of opaque mask pattern layers 12a, 12b and 12c.

The pair of patterned masking layers 14a and 14b may be stripped employing methods as are conventional in the photomask fabrication art, which may include, but are not limited to wet chemical stripping methods, dry plasma stripping methods and aggregate methods thereof.

FIG. 5 illustrates a schematic plan-view diagram of a repaired photomask in accord with a first preferred embodiment of the invention. The repaired photomask is efficiently repaired since the repaired photomask is repaired while employing a patterned masking layer (which leaves exposed only a minimum of one opaque mask pattern layer defect) as a mask defect repair mask layer. Use of the patterned masking layer allows for a global wet chemical etch and/or dry plasma etch for etching the opaque mask pattern layer defect such as to provide more rapid removal of the opaque mask pattern layer defect absent transparent substrate over-etching, as is common when employing a focused ion beam method for effecting a repair to a defective photomask.

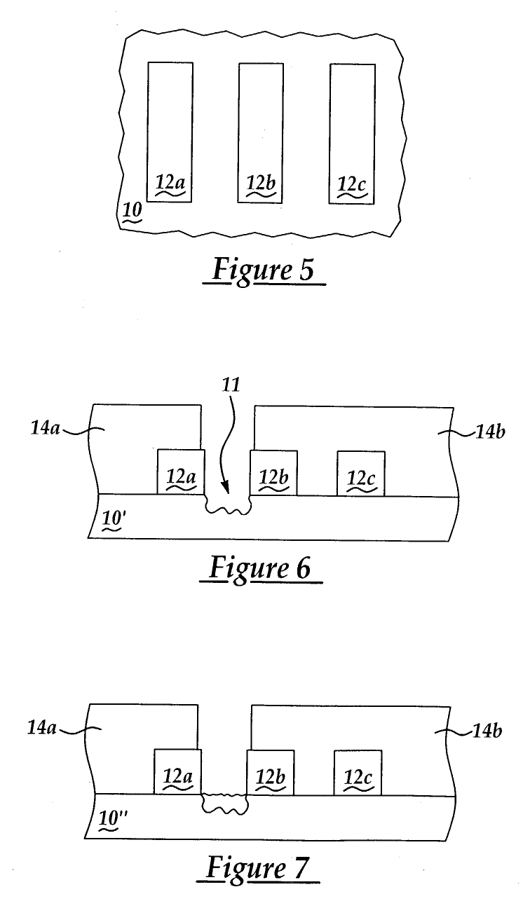

FIG. 6 and FIG. 7 show a pair of schematic cross-sectional diagrams illustrating the results of progressive stages in repairing a defective photomask in accord with a second preferred embodiment of the invention.

FIG. 6 shows a schematic cross-sectional diagram of the defective photomask at an earlier stage in its repair in accord with the second preferred embodiment of the invention.

FIG. 6 illustrates a defective photomask generally analogous to the defective photomask whose schematic cross-sectional diagram is illustrated in FIG. 3. However, instead of a transparent substrate 10 having formed thereupon an opaque mask pattern layer defect 12d, the defective photomask mask instead comprises a defective transparent substrate 10′ having formed therein a transparent substrate defect 11 in form of a crater interposed between the pair of opaque mask pattern layers 12a and 12b within the series of opaque mask pattern layers 12a, 12b and 12c. The pair of patterned masking layers 14a and 14b is otherwise sized generally analogously, equivalently or identically to the pair of patterned masking layers 14a and 14b as illustrated within FIG. 3.

FIG. 7 shows a schematic cross-sectional diagram illustrating the results of further processing of the defective photomask of FIG. 6.

FIG. 7 illustrates the results of repairing the defective transparent substrate 10′ by filling the transparent substrate defect 11 in the form of the crater therein to thus form a repaired defective transparent substrate 10″.

Within the second preferred embodiment of the invention, the transparent substrate defect 11 may be filled employing a thermally or photochemically activated chemical vapor deposition (CVD) method, or any of several other deposition methods, such as but not limited to a physical vapor deposition (PVD) method, to provide the repair to the repaired defective transparent substrate 10″ of appropriate index of refraction. Within the second preferred embodiment of the invention, the pair of patterned masking layers 14a and 14b protects the series of opaque mask pattern layers 12a, 12b and 12c and remaining portions of the defective transparent substrate 10′ when repairing the transparent substrate defect 11.

As is understood by a person skilled in the art, the preferred embodiments of the invention are illustrative of the invention rather than limiting of the invention. Revisions and modifications may be made to materials, structures and dimensions in accord with the preferred embodiments of the invention while still providing additional embodiments of the invention, further in accord with the accompanying claims.

What is claimed is:

1. A method for repairing a defective mask comprising:
providing a defective mask having contained therein a minimum of one defect;
forming upon the defective mask a masking layer which leaves exposed the minimum of one defect; and
repairing within the defective mask the minimum of one defect while employing the masking layer as a defect repair masking layer, to thus form from the defective mask a repaired mask.

2. The method of claim 1 wherein the minimum of one defect is selected from the group consisting of mask pattern layer defects and transparent substrate defects.

3. The method of claim 1 wherein the masking layer leaves exposed only the minimum of one defect.

4. The method of claim 1 wherein the masking layer is formed of a hard masking material.

5. The method of claim 1 wherein the masking layer is formed of a photoresist masking material.

6. The method of claim 1 wherein the masking layer is formed of a positive photoresist masking material.

7. The method of claim 6 wherein the positive photoresist masking material is photoexposed employing a method selected from the group consisting of scanning electron microscopy methods, electron beam methods, ion beam methods and optical methods.

8. The method of claim 1 further comprising stripping the masking layer from the repaired photomask.

9. A method for repairing a defective mask comprising:
providing a defective mask having contained therein a minimum of one mask pattern layer defect;
forming upon the defective mask a masking layer which leaves exposed the minimum of one mask pattern layer defect; and
repairing within the defective mask the minimum of one mask pattern layer defect while employing the masking layer as a defect repair masking layer, to thus form from the defective mask a repaired mask.

10. The method of claim 9 wherein the minimum of one mask pattern layer defect has an areal dimension of from about 0.01 to about 1 square microns.

11. The method of claim 9 wherein the minimum of one mask pattern layer defect is repaired employing a wet chemical etch method.

12. The method of claim 9 wherein the minimum of one mask pattern layer defect is repaired employing a plasma etch method.

13. The method of claim 9 wherein the masking layer leaves exposed only the minimum of one mask pattern layer defect.

14. The method of claim 9 wherein the masking layer is formed of a positive photoresist masking material.

15. The method of claim 14 wherein the positive photoresist masking material is photoexposed employing a method selected from the group consisting of scanning electron microscopy methods, electron beam methods, ion beam methods and optical methods.

16. A method for repairing a defective mask comprising:
providing a defective mask having contained therein a minimum of transparent substrate defect;
forming upon the defective mask a masking layer which leaves exposed the minimum of one transparent substrate defect; and
repairing within the defective mask the minimum of one transparent substrate defect while employing the masking layer as a defect repair masking layer, to thus form from the defective mask a repaired mask.

17. The method of claim 16 wherein the minimum of one transparent substrate defect has areal dimensions of from about 0.01 to about 1 square microns.

18. The method of claim 16 wherein the masking layer leaves exposed only the minimum of one transparent substrate defect.

19. The method of claim 16 wherein the masking layer is formed of a positive photoresist masking material.

20. The method of claim 19 wherein the positive photoresist masking material is photoexposed employing a method selected from the group consisting of scanning electron microscopy methods, electron beam methods, ion beam methods and optical methods.
